(19) United States
(12) Patent Application Publication
(10) Pub. No.: US 2010/0188804 A1
(43) Pub. Date: Jul. 29, 2010

(54) DISPLAY DEVICE

(75) Inventors: Woon-Geun Jang, Gumi-City (KR); Jae-Woong Na, Gumi-City (KR); Seung-Jin Baek, Gumi-City (KR); Sung-Hoon Hwang, Gumi-City (KR); Yong-Han Yoon, Gumi-City (KR); Young-Seok Chae, Gumi-City (KR)

Correspondence Address: BIRCH STEWART KOLASCH & BIRCH, PO BOX 747, FALLS CHURCH, VA, 22040-0747, US

(73) Assignee: LG Electronics Inc., Seoul (KR)

(21) Appl. No.: 12/521,714

(22) PCT Filed: Dec. 28, 2007
(86) PCT No.: PCT/KR2007/006980

§ 371 Date: Mar. 10, 2010

(30) Foreign Application Priority Data
Jan. 2, 2007 (KR) 10-2007-0000358

(51) Int. Cl. H05K 7/00

(52) U.S. Cl. 361/679.01

(57) ABSTRACT

Provided is a display device. The display device includes a main body, a coupling portion, a first elevating member, a second elevating member, a guide unit, and a base. The main body receives a display module. The coupling portion is connected to a rear side of the main body. The first elevating member is coupled to the coupling portion. The second elevating member is rotatably coupled with respect to the first elevating member. The guide unit supports the first and second elevating members. The base supports the guide unit.

### TECHNICAL FIELD

An embodiment of the present disclosure relates to a display device, and more particularly, to a display device that can control the position of the display device to various convenient positions.

### BACKGROUND ART

A display device includes a main body provided with a module, a stand that can control the position of the main body to various angles, and a base supporting the stand.

The stand is designed for controlling the position of the main body, and generally includes a height control function of vertically moving the main body. However, when a user intends to pull the main body to the front and view the display device at a closer position, the user should inconveniently move the entire display device including the base to the front.

That is, there is inconvenience of having to move the entire display device to pull the position of the main body to the front. Of course, to solve this limitation, the stand itself has an inclined structure, and the main body can be pulled to the front using the inclination of the stand.

However, since a distance by which the stand can move through the movement of the stand itself is limited, a user cannot control the main body over a wide width.

Also, to provide the stand having the inclined structure, the structure is complicated and costs thereof is expensive.

### DISCLOSURE OF INVENTION

### Technical Problem

Embodiments provide a display device that allows a main body to move to the front by a considerable distance and allows a user to conveniently manipulate the position of the main body.

### Technical Solution

In one embodiment, a display device includes: a main body receiving a display module; a coupling portion connected to a rear side of the main body; a first elevating member coupled to the coupling portion; a second elevating member rotatably coupled with respect to the first elevating member; a guide unit supporting the first and second elevating members; and a base supporting the guide unit.

In another embodiment, a display device includes: a main body; a first elevating member having one side connected to the main body; a hinge unit allowing the first elevating member to rotate; a second elevating member coupled to the hinge unit; and a guide unit guiding elevating operations of the first and second elevating members, at least one of the first elevating member and the hinge unit being drawable from the guide unit.

### Advantageous Effects

According to an embodiment, since the position of the main body can be used within a wide use range, a user who intends to draw the main body has only to move the main body to the upper side and rotate the main body to the front. Furthermore, since these operations can be performed by a simple mechanical construction, manufacturing costs may reduce and user convenience may improve.

### BRIEF DESCRIPTION OF THE DRAWINGS

FIG. 1 is a perspective view of a display device according to an embodiment.

FIG. 2 is a cross-sectional view taken along the line II-II′ of FIG. 1.

FIG. 3 is a cross-sectional view taken along the line I-I′ of FIG. 1.

FIG. 4 is a perspective view of the rear side of a hinge body while a main body is drawn to the front.

FIG. 5 is a view illustrating a main body lowered to the lower side.

FIG. 6 is a view illustrating a main body raised to the upper side.

FIG. 7 is a view illustrating a first elevating member drawn to the front of a support portion.

FIG. 8 is a view illustrating the angle of a main body controlled by a display device.

### MODE FOR THE INVENTION

Reference will now be made in detail to the embodiments of the present disclosure, examples of which are illustrated in the accompanying drawings.

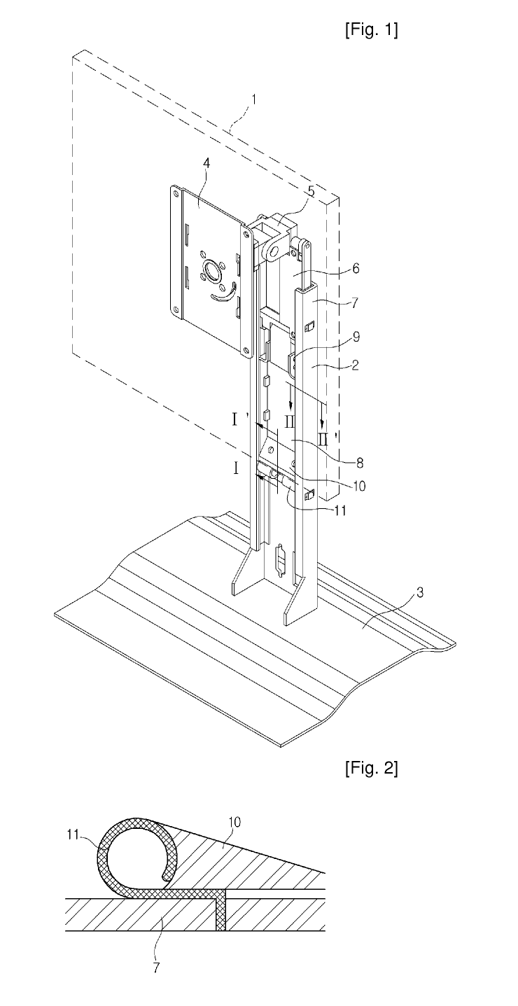

FIG. 1 is a perspective view of a display device according to an embodiment.

Referring to FIG. 1, the display device includes a main body 1 receiving a display module in its inside, a stand 2 provided to the rear of the main body 1, and a base 3 supporting the stand 2.

In detail, the stand 2 includes a guide unit 7 that is erect with respect to the base 3, and a first elevating member 6 and a second elevating member 8 whose elevating operations are guided by the guide unit 7.

Also, a hinge unit 9 allowing the first elevating member 6 to rotate with respect to the second elevating member 8 is formed at a connection portion between the first elevating member 6 and the second elevating member 8.

Here, the guide unit 7 is fixed in the base 3. The first and second elevating members 6 and 8 are configured to vertically move inside the guide unit 7.

The first elevating member 6 can be detached from the end of the guide unit 7, but the second elevating member 8 is not detached from the end of the guide unit 7. For this purpose, a stopper 13 (of FIG. 2) is provided inside the guide unit 7, and the second elevating member 8 has left and right ends greater than those of the first elevating member 6.

Also, the hinge unit 9 can be also detached from the end of the guide unit 7 so that the first elevating member 6 can rotate after the first elevating member 6 is detached from the guide unit 7.

Here, it is necessary to define a construction allowing the first elevating member 6 and the hinge unit 9 to be drawn from the guide unit 7.

That is, for the first elevating member 6 to rotate as illustrated in FIG. 4 after the first elevating member 6 moves along the guide unit 7, the hinge unit 9 provided for rotation of the first elevating member 6 should be also detached from the guide unit 7. In this case, the first elevating member 6 and the hinge unit 9 are drawn from the guide unit 7.

In this case, since a portion of the second elevating member 8 can be detached from the end of the guide unit 7 but the second elevating member 8 is not completely detached from the guide unit 7 to support the first elevating member 6, the second elevating member 8 can be configured not to be drawn from the guide unit 7.

Meanwhile, a coupling portion 5 for coupling to the main body 1 is formed at the one end of the first elevating member 6. The coupling portion 5 includes a plurality of hinges.

Accordingly, the coupling portion 5 can be configured to allow the main body 1 to rotate pivotally, rotate vertically, and rotate horizontally. In this respect, the coupling portion 5 can be called a hinge body, which will be described below with reference to the accompanying drawings.

The coupling portion 5 is connected to a rear fixing portion 4 connected to the main body 1. The rear fixing portion 4 can be rotated by the coupling portion 5. In FIG. 1, the rear fixing portion 4 is bent to the front by the coupling portion 5.

Also, the second elevating member 8 generates predetermined frictional force while moving vertically to support the weight of the main body 1.

FIG. 2 is a cross-sectional view taken along the line I-I′ of FIG. 1. An operation of supporting the weight of the main body is described with reference to FIG. 2.

One end of a spring 11 is hooked at the guide unit 7. The other end of the spring 11 is compressed. The spring 11 can be exemplified as a windup spring. Also, the spring 11 is compressed by a pushing portion 10 formed at the second elevating member 8.

That is, the pushing portion 10 is integrally formed with the second elevating member 8. When the second elevating member 8 moves to the lower side due to the weight of the main body 1, the weight of the second elevating member 8 is reduced by elastic force of the spring 11.

Also, when a user raise the second elevating member 8 to the upper side, the second elevating member 8 and the main body 1 can be moved by the elastic force of the spring 11.

When the second elevating member 8 is pushed to the lower side by the above-described construction, the pushing portion 10 pushes the spring 11. The winding of the spring 11 is released to provide restoring force to the pushing portion 10. Accordingly, the weight of the main body 1 is supported by the restoring force of the spring 11.

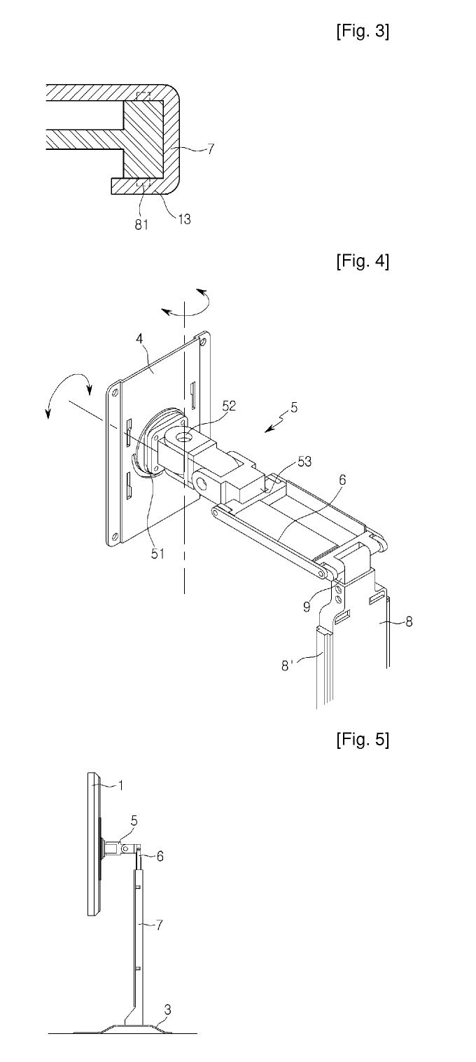

FIG. 3 is a cross-sectional view taken along the line II-II′ of FIG. 1. The elevating operations of the elevating members 6 and 8 will be described in more detail with reference to FIG. 3.

The guide unit 7 is fixed in the base 3 and extends upward. The first and second elevating members 6 and 8 are received inside the guide unit 7.

Here, the first elevating member 6 is provided to be drawable to the above of the guide unit 7, but the second elevating member 8 is provided not to be drawn (detached) from the upper side of the guide unit 7.

To allow a mutual hooking operation between the second elevating member 8 and the guide unit 7 to be performed, protrusions 81 are formed on the both ends of the second elevating member 8, respectively.

In this case, when a user intends to control the vertical position of the main body 1, the user moves the elevating members 6 and 8 to the upper direction along the guide unit 7.

At this point, the user can control the vertical position of the main body 1 using even small force due to the elastic force applied from the spring 11.

While the user pulls the main body 1 upward, the main body 1 can be moved upward up to a position where the first elevating member 6 and the hinge unit 9 are detached from the guide unit 7.

However, when the second elevating member 8 reaches the upper end of the guide unit 7, the end of the second elevating member 8 is hooked at the stopper 13 formed inside the guide unit 7, so that the second elevating member 8 is not drawn from the guide unit 7.

Therefore, the user can accurately know the movement limits of the first and second elevating members 6 and 8.

After that, the user can rotate the first elevating member 6 to the front using the hinge unit 9 as a rotational center. The first elevating member 6 is drawn to the front by the hinge unit 9, the main body 1 moves toward the user. Therefore, the user can view the display device at a closer distance.

FIG. 4 is a perspective view of the rear side of the coupling portion while the main body is drawn to the front.

Referring to FIG. 4, the coupling portion 5 is provided for various rotation of the main body 1, and includes a plurality of hinges, so that it can be called a hinge body.

The coupling portion 5 is a portion provided to allow the main body 1 to have movements of various degrees of freedom.

For this purpose, a pivot hinge 51 and a swivel hinge 52 are provided between the rear fixing portion 4 and the first elevating member 6 on the coupling portion 5. Of course, an inclination hinge 53 is also provided.

In detail, the pivot hinge 51 is a hinge that allows the main body 1 to rotate clockwise or counterclockwise. Therefore, when the user takes the main body 1 and rotates the main body 1 clockwise or counterclockwise at the front, the main body 1 can swiftly move through the relative rotational motion of the pivot hinge 51.

Here, the swivel hinge 52 is a hinge that rotates the main body 1 in a horizontal direction, and the inclination hinge 53 is a hinge that rotates the main body 1 in a vertical direction.

Each hinge can be easily understood when arrows denoting the rotational axes of the hinges 51, 52, and 53 are referred.

Meanwhile, when the first elevating member 6 is drawn to the outside of the guide unit 7, a distance between the main body 1 and the stand 2 is considerably long, so that the user can take the main body 1 and conveniently move the main body 1.

That is, even when the main body 1 moves to any position, the main body 1 is not caught on the stand 2 and so it is convenient. Of course, there is convenience that the user can get closer to the main body 1.

Though the above-described hinges 51, 52, and 53 are not described in detail, a general construction can be applied to the hinges. Furthermore, a friction member is provided to each hinge to give frictional force against a rotational operation when each counterpart member rotates.

The detailed construction and operation of the each part would be understood by the above description. A state where the display device can be put will be described below.

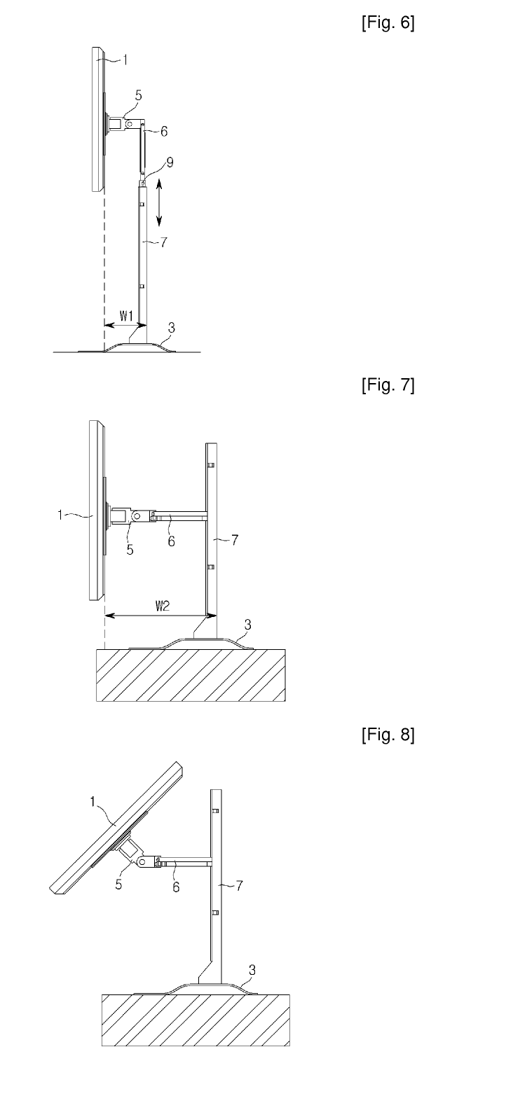

First, according to the display device, the elevating members 6 and 8 move vertically while they are guided by the guide unit 7. In other words, the elevating members 6 and 8 can move vertically in a straight line direction. FIG. 5 illustrates the main body lowered down to the lower side, and FIG. 6 illustrates the main body raised to the upper side.

The elevating member can move vertically as described above, and the main body 1 can perform inclination rotation, pivot rotation, and swivel rotation through the operation of the coupling portion 5.

These states can be used when a user moves the main body to view the main body in various directions while maintaining a predetermined interval from the main body.

Meanwhile, FIG. 6 illustrates the guide unit 7 and the main body 1 are separated from each other while maintaining a small distance W1 therebetween. In some cases, the user intends to wide the interval between the guide unit and the main body. For example, the user may pull a chair and sit on it, and then push the chair to the rear to sit comfortably.

In this case, the main body 1 can be drawn to the front by rotating the first elevating member 6 with respect to the hinge unit 9.

Also, the second elevating member 8 can be lowered down again to the lower side along the guide unit 7 to adjust a height. Of course, in this case, the first elevating member 6 is drawn to the front of the guide unit 7, which is illustrated in detail in FIG. 7.

Then, a large interval W2 is maintained between the guide unit 7 and the main body 1. When the interval between the guide unit 7 and the main body 1 increases, the interval between the user and the main body 1 decreases, so that the user can view a large screen at closer distance and user convenience increases.

Meanwhile, when the main body 1 is lowered down to a far lower position, the user may be inconvenient. In this case, the coupling portion 5 (that is, the hinge body) is operated to control the main body 1 upward at an excessive angle. FIG. 8 illustrates this case in detail.

According to an embodiment, since the main body can be drawn to the front considerably, user convenience improves. Furthermore, since the above-described effect can be achieved by a simple structure in which manipulation of the user is simple and one more auxiliary hinge is applied, manufacturing costs reduce.

Another embodiment included in the spirit of the present disclosure will be described.

Though description has been made that both ends of the second elevating member 8 are hooked at the guide unit 7 so that the second elevating member 8 is not detached, it would be obvious to those having ordinary skill in the art that the rear side, not both ends of the second elevating member 8 may be hooked at the guide unit 7.

Also, the second elevating member 8 can be detached from the guide unit 7 using a spring member for convenience in repair and movement according to another embodiment.

Though the elevating member includes the first elevating member and the second elevating member separated from each other, the elevating member is not limited thereto but a third elevating member can be further provided in the same configuration, or it would be obvious to those having ordinary skill in the art to provide the more number of elevating members.

### INDUSTRIAL APPLICABILITY

Since an embodiment is applicable to a display device, it has industrial applicability.

1. A display device comprising:
a main body receiving a display module;
a coupling portion connected to a rear side of the main body;
a first elevating member coupled to the coupling portion;
a second elevating member rotatably coupled with respect to the first elevating member;
a guide unit supporting the first and second elevating members; and
a base supporting the guide unit.

2. The display device according to claim 1, wherein the coupling portion comprises a pivot hinge rotating the main body clockwise or counterclockwise.

3. The display device according to claim 1, wherein the coupling portion comprises a swivel hinge rotating the main body in a horizontal direction.

4. The display device according to claim 1, wherein the coupling portion comprises an inclination hinge rotating the main body in a vertical direction.

5. The display device according to claim 1, wherein the coupling portion is a hinge rotating the main body, the coupling portion comprising at least one of a hinge rotating the main body clockwise or counterclockwise, a hinge rotating the main body in a horizontal direction, and a hinge rotating the main body in a vertical direction.

6. The display device according to claim 1, wherein the first elevating member and the second elevating member are received inside the guide unit.

7. The display device according to claim 1, wherein a pushing portion protruding by a predetermined thickness is formed on the second elevating member, and a spring providing elastic force to the pushing portion is formed on the guide unit.

8. The display device according to claim 7, wherein the spring has one side fixed to the guide unit and has a shape rolled when the second elevating member moves upward.

9. The display device according to claim 1, wherein a protrusion protruding by a predetermined thickness is formed on one side of the second elevating member, and a stopper is formed in the guide unit to catch the protrusion.

10. A display device comprising:
a main body;
a first elevating member having one side connected to the main body;
a hinge unit allowing the first elevating member to rotate;
a second elevating member coupled to the hinge unit; and
a guide unit guiding elevating operations of the first and second elevating members, at least one of the first elevating member and the hinge unit being drawable from the guide unit.

11. The display device according to claim 10, wherein a rotational motion of the first elevating member is performed when the first elevating member and the hinge unit are drawn from the guide unit.

12. The display device according to claim 10, wherein a portion of the second elevating member does not get out of the guide unit.

13. The display device according to claim 12, wherein a protrusion protruding by a predetermined thickness is formed on one side of the second elevating member, and a stopper is formed in the guide unit to limit a movement distance of the protrusion.

14. The display device according to claim 10, further comprising a hinge body for rotation of the main body between the main body and the first elevating member.

15. The display device according to claim 14, wherein the hinge body comprises one of an inclination hinge, a swivel hinge, and a pivot hinge.
